(19) United States
(12) Patent Application Publication
(10) Pub. No.: US 2009/0084501 A1
(43) Pub. Date: Apr. 2, 2009

(54) Processing system for producing a negative ion plasma

(75) Inventors: Lee CHEN, Cedar Creek, TX (US); Merritt FUNK, Austin, TX (US)

Correspondence Address: TOKYO ELECTRON U.S. HOLDINGS, INC., 4350 W. CHANDLER BLVD., SUITE 10, CHANDLER, AZ, 85226, US

(73) Assignee: TOKYO ELECTRON LIMITED, Tokyo (JP)

(21) Appl. No.: 11/862,358

(22) Filed: Sep. 27, 2007

(51) Int. Cl. H01L 21/306

(52) U.S. Cl. 156/345.26; 156/345.1

(57) ABSTRACT

A processing system for producing a negative ion plasma is described, wherein a quiescent plasma having negatively-charged ions is produced. The processing system comprises a first chamber region for generating plasma using a first process gas, and a second chamber region separated from the first chamber region with a separation member. Electrons from plasma in the first region are transported to the second region to form quiescent plasma through collisions with a second process gas. A pressure control system coupled to the second chamber region is utilized to control the pressure in the second chamber region such that the electrons from the first chamber region undergo collision-quenching with the second process gas to form less energetic electrons that produce the quiescent plasma having negatively-charged ions.

### BACKGROUND OF THE INVENTION

1. Field of the Invention

The invention relates to a system for producing plasma with negatively-charged ions and, more particularly, to a system for producing a neutral beam derived from plasma having negatively-charged ions.

2. Description of Related Art

During material processing, such as semiconductor processing, plasma is often utilized to assist etch processes by facilitating the anisotropic removal of material along fine lines or within vias (or contacts) patterned on a semiconductor substrate. For example, pattern etching can comprise the application of a thin layer of radiation-sensitive material, such as photoresist, to an upper surface of a substrate that is subsequently patterned in order to provide a mask for transferring this pattern to the underlying thin film on a substrate during etching.

However, conventional plasma processes that utilize electropositive plasma discharge (population of positive ions and electrons) for substrate treatment pose greater risk for charge-induced damage of material layers and devices formed on the substrate. For example, due to the substantial difference in mobility between ions and electrons, ions may penetrate deeper into device features (relative to electrons), thus causing gradients in charge on the substrate which may cause electrical breakdown when the field strength becomes sufficiently large. As devices have become smaller and integration densities have increased, breakdown voltages of insulation and isolation structures therein have, in many instances, been markedly reduced, often to much less than ten volts. For example, some integrated circuit (IC) device designs call for insulators of sub-micron thicknesses.

At the same time, as material structures (i.e., film thicknesses, feature critical dimensions, etc.) continue to shrink, the susceptibility to charging damage dramatically increases. The reduction of the size of structures reduces the capacitance value of the insulation or isolation structures, and relatively fewer charged particles are required to develop an electric field of sufficient strength to break down insulation or isolation structures. Therefore, the tolerance of semiconductor structures for the charge carried by particles impinging on them during the manufacturing process, such as a dry plasma etching process, has become quite limited and the structures for dissipating such charges during manufacture are sometimes required, often complicating the design of the semiconductor device.

Consequently, material processes during IC fabrication contemplate the use of ion-ion plasma discharge (from electronegative gas) to facilitate anisotropic treatment of a substrate. Therein, both positive ions and negative ions can be drawn to the substrate for processing in order to reduce or minimize charge-induced damage.

Further, material processes contemplate the use of a neutral beam to facilitate anisotropic treatment of a substrate. Therein, energetic neutral particles are created and directed toward the substrate to facilitate such anisotropic processing.

The term “neutral beam” has been applied in the literature to a space-charge neutralized beam but which may contain relatively few neutral particles, if any. The term is therefore correct only in the macroscopic sense that there will be substantially equal populations of electrons and ions. However, as used herein, the term “neutral beam” will be used to connote a beam containing a significant population of neutral particles in which electrons and ions are bound in the neutral particle.

In neutral beam process technology, (dense) plasma is formed containing ionized gaseous constituents suitable for treating the substrate. Due to the electrical charge associated with these ionized gaseous constituents, an electric field is utilized to guide their initial trajectory and accelerate these ion species to an energy level sufficient to maintain their trajectory once they are neutralized. As an example, a neutralizer grid having a plurality of apertures may be placed in line with the energetic beam of ion species. As the ion species pass through these apertures, they recombine with electrons as in the case of positive ions or lose one or more electrons as in the case of negative ions to form an energetic neutral beam having a trajectory substantially normal to the substrate.

Generally, the production of neutral particle beams has focused on the neutralization of positive ions. However, this methodology may be less practical. The neutralization process for positive ions relies on accelerating positive ions and, through collisions, exchanging charge, which may be less efficient. Alternatively, neutral particle beams focusing on the neutralization of negative ions may be more practical. The neutralization process for negative ions relies on stripping electrons, which requires less energy and may be more efficient. The difficulty lies in production of plasma having a substantial population of negative ions.

### SUMMARY OF THE INVENTION

The invention relates to a system for producing plasma with negatively-charged ions. In particular, the invention relates to a system for producing a neutral beam derived from plasma having negatively-charged ions.

Furthermore, the invention relates to a system for efficient production of negative ions while allowing the creation of a narrow-band energy spectrum for negative ions extracted from the plasma. If the extracted negative ions are neutralized, then the resulting neutral beam may possess narrow-band neutral beam energy.

According to an embodiment, a processing system for producing a negative ion plasma is described, wherein a quiescent plasma having negatively-charged ions is produced. The processing system comprises a first chamber region for generating plasma using a first process gas, and a second chamber region separated from the first chamber region with a separation member. Electrons from plasma in the first region are transported to the second region to form quiescent plasma through collisions with a second process gas. A pressure control system coupled to the second chamber region is utilized to control the pressure in the second chamber region such that the electrons from the first chamber region undergo collision-quenching with the second process gas to form less energetic electrons that produce the quiescent plasma having negatively-charged ions.

According to another embodiment, a processing system for producing plasma containing negatively-charged ions is described, comprising: a first chamber configured to receive a first process gas and operate at a first pressure; a first gas injection system coupled to the first chamber and configured to introduce the first process gas; a second chamber coupled to the first chamber, and configured to receive a second process gas and operate at a second pressure, wherein the second chamber comprises an outlet configured to be coupled to a substrate treatment system for processing a substrate; a second gas injection system coupled to the second chamber and configured to introduce the second process gas; a plasma generation system coupled to system first chamber and configured to form plasma from the first process gas; a separation member disposed between the first chamber and the second chamber, wherein the separation member comprises one or more openings configured to supply electrons from the plasma in the first chamber to the second chamber in order to form a quiescent plasma in the second chamber; and a pressure control system coupled to the first chamber or the second chamber or both, and configured to control the second pressure such that the electrons from the first chamber undergo collision-quenching with the second process gas to form less energetic electrons that produce the quiescent plasma with negatively-charged ions in the second chamber, wherein the second process gas comprises at least one electronegative gaseous specie.

According to an additional embodiment, a negatively-charged-ion-generated neutral beam source is described, comprising: a neutral beam generation chamber comprising a first chamber region configured to receive a first process gas and operate at a first pressure, and a second chamber region disposed downstream of the first chamber region and configured to receive a second process gas and operate at a second pressure; a first gas injection system coupled to the first chamber region and configured to introduce the first process gas; a second gas injection system coupled to the second chamber region and configured to introduce the second process gas; a plasma generation system coupled to the first chamber region and configured to form plasma from the first process gas; a separation member disposed between the first chamber region and the second chamber region, wherein the separation member comprises one or more openings configured to allow the transport of electrons from the plasma in the first chamber region to the second chamber region in order to form a quiescent plasma in the second chamber region; a pressure control system coupled to the neutral beam generation chamber, and configured to control the second pressure such that the electrons from the first chamber region undergo collision-quenching with the second process gas to form less energetic electrons that produce the quiescent plasma with negatively-charged ions; and a sub-Debye neutralizer grid coupled to the outlet of the second chamber region, and configured to partly or fully neutralize the negatively charged ions.

### BRIEF DESCRIPTION OF THE DRAWINGS

In the accompanying drawings:

FIG. 1 illustrates a processing system according to an embodiment;

FIG. 2 illustrates a processing system according to an embodiment;

FIG. 3A provides an exploded view of an opening in a separation member according to an embodiment;

FIG. 3B provides an exploded view of an opening in a neutralizer grid according to an embodiment;

FIG. 4 illustrates a processing system for treating a substrate according to an embodiment;

FIG. 5 illustrates a processing system according to an embodiment; and

FIG. 6 illustrates a processing system according to an embodiment.

### DETAILED DESCRIPTION OF EXEMPLARY EMBODIMENTS

In the following description, for purposes of explanation and not limitation, specific details are set forth, such as particular processing systems including plasma processing systems and neutral beam processing systems for treating a substrate. However, it should be understood that the invention may be practiced in other embodiments that depart from these specific details.

According to an embodiment, a system for producing a negative ion plasma is described, wherein a quiescent plasma having negatively-charged ions is produced. The processing system comprises a first chamber region for generating plasma using a first process gas, and a second chamber region separated from the first chamber region with a separation member. Electrons from plasma in the first chamber region are transported to the second chamber region to form quiescent plasma through collisions with a second process gas. The term “quiescent” plasma is used herein to distinguish plasma formed in the second chamber region from plasma formed in the first chamber region. For instance, plasma is created in the first chamber region by coupling electromagnetic (EM) energy into the first process gas to heat electrons, while plasma is created in the second chamber region by transporting electrons from the first chamber region to the second chamber region to interact with the second process gas. A pressure control system coupled to the second chamber region is utilized to control the pressure in the second chamber region such that the electrons from the first chamber region undergo collision-quenching with the second process gas to form less energetic electrons that produce the quiescent plasma having negatively-charged ions.

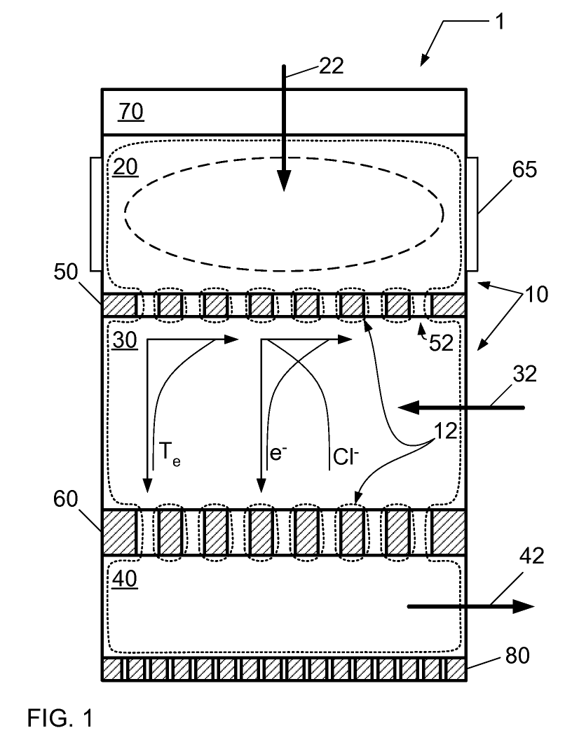

The system may facilitate efficient production of negative ions (i.e., an ion-ion plasma) while allowing the creation of a (relatively) narrow energy spectrum for negative ions extracted from the plasma. If the extracted negative ions are neutralized, then the resulting neutral beam may possess a (relatively) narrow neutral beam energy. Referring to FIG. 1, a processing system 1 is illustrated for producing a neutral beam using negative ion plasma formation and extraction.

The processing system 1 comprises a neutral beam generation chamber 10 comprising a first chamber region 20 configured to receive a first process gas 22 at a first pressure, and a second chamber region 30 disposed downstream of the first chamber region 20 and configured to receive a second process gas 32 at a second pressure. The second process gas 32 comprises at least one electronegative gas. A plasma generation system 70 is coupled to the first chamber region 20 and configured to form plasma (as indicated by the dashed line) from the first process gas 22.

Furthermore, as illustrated in FIG. 1, a plasma sheath 12 forms at the confining surfaces of the neutral beam generation chamber 10 (as indicated by the dotted line). As described above, the plasma sheath represents a boundary layer between the bulk plasma and a confining surface, such as a confining conductive surface. Generally, the plasma sheath follows closely the conductive surface that confines the plasma except near a discontinuity in the surface, such as the entrance to an aperture (e.g., an opening or orifice formed through the confining surface). The plasma sheath does not follow the aperture when the aperture size (i.e., transverse dimension or diameter) is less than the Debye length.

Referring still to FIG. 1, a separation member 50 is disposed between the first chamber region 20 and the second chamber region 30, wherein the separation member 50 comprises one or more openings 52 configured to allow transport of electrons from the plasma in the first chamber region 20 to the second chamber region 30 in order to form a quiescent plasma in the second chamber region 30. The openings 52 in the separation member 50 may comprise super-Debye length apertures, i.e., the transverse dimension or diameter is larger than the Debye length. The openings may be sufficiently large to permit adequate electron transport, and the openings may be sufficiently small to prevent or reduce electron heating across the separation member 50.

Additionally, a pressure control system 42 is coupled to the processing system 1, and configured to control the second pressure. Electrons from the first chamber region 20 may undergo collision-quenching with the second process gas to form less energetic electrons that produce the quiescent plasma with negatively-charged ions in the second chamber region.

Processing system 1 also comprises a neutralizer grid 80 coupled to an outlet of the processing system 1, and configured to partly or fully neutralize the negatively charged ions. The neutralizer grid 80 may be coupled to ground or it may be electrically biased. The neutralizer grid 80 may be a sub-Debye neutralizer grid as will be discussed in greater detail later.

Optionally, the processing system 1 may include a third chamber region 40 disposed downstream of the second chamber region 30, wherein an outlet of the third chamber region 40 is coupled to the neutralizer grid 80. A pressure barrier 60 may be disposed between the second chamber region 30 and the third chamber region 40, and configured to produce a pressure difference between the second pressure in the second chamber region 30 and a third pressure in the third chamber region 40, the third pressure less than the second pressure. The openings in the pressure barrier 60 may comprise super-Debye length apertures. The openings may be sufficiently small to allow a pressure difference between the second chamber region 30 and the third chamber region 40.

Optionally, the processing system 1 may comprise one or more electrodes 65 located about a periphery of the first chamber region 20 and configured to contact the plasma. A power source may be coupled to the one or more electrodes 65 and configured to couple an electrical voltage to the one or more electrodes 65. The one or more electrodes 65 may include a powered cylindrical electrode configured to act as a cylindrical hollow-cathode. For example, the one or more electrodes 65 may be utilized to reduce the plasma potential of the plasma formed in the first chamber region 20 or reduce the electron temperature or both.

As illustrated in FIG. 1, electrons are transported from the first chamber region 20 to the second chamber region 30 through separation member 50. The electron transport may be driven by diffusion, or it may be driven by field-enhanced diffusion. As electrons emerge from the separation member 50 and enter the second chamber region 30, they undergo collisions with the second process gas and lose energy causing the electron temperature to decrease (as shown in FIG. 1). For illustration purposes, the second process gas 32 comprises chlorine (Cl₂) as an electronegative gas.

When the electron temperature decreases, the electronegative gas specie(s) of the second process gas (e.g., Cl₂) undergoes (dissociative) electron attachment, viz.

Cl₂+e→Cl⁻+Cl, (3)

As the electron temperature decreases, the electron concentration (e⁻) decreases and the concentration of negatively charged chlorine ions (Cl⁻) increases (see the illustrations in FIG. 1). The electronegative gas specie(s) can be introduced with the first process gas 22; however, the efficiency for producing negatively charged ions would be reduced.

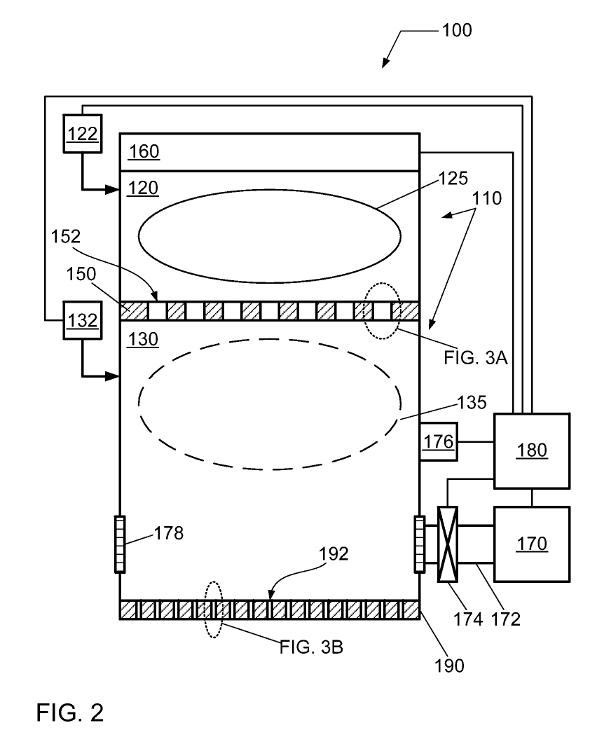

Referring now to FIG. 2, a processing system 100 is provided for producing a negative ion plasma according to an embodiment. The processing system 100 comprises a process chamber 110 comprising a first chamber region 120 configured to receive a first process gas at a first pressure, and a second chamber region 130 disposed downstream of the first chamber region 120 and configured to receive a second process gas at a second pressure.

A first gas injection system 122 is coupled to the first chamber region 120, and configured to introduce the first process gas. The first process gas may comprise an electropositive gas (e.g. Ar or other noble gases) or an electronegative gas (e.g., Cl₂, O₂, etc.) or a mixture thereof. For example, the first process gas may comprise a noble gas, such as Ar. The first gas injection system 122 may include one or more gas supplies or gas sources, one or more control valves, one or more filters, one or more mass flow controllers, etc.

A second gas injection system 132 is coupled to the second chamber region 130, and configured to introduce the second process gas. The second process gas comprises at least one electronegative gas (e.g., O₂, N₂, Cl₂, HCl, CCl₂F₂, SF₆, etc.). The second gas injection system 132 may include one or more gas supplies or gas sources, one or more control valves, one or more filters, one or more mass flow controllers, etc.

A plasma generation system 160 is coupled to the first chamber region 120 and configured to form plasma 125 (as indicated by the solid line) from the first process gas. The plasma generation system 160 comprises at least one of a capacitively coupled plasma source, an inductively coupled plasma source, a transformer coupled plasma source, a microwave plasma source, a surface wave plasma source, or a helicon wave plasma source.

For example, the plasma generation system 160 may comprise an inductive coil to which radio frequency (RF) power is coupled via a RF generator through an optional impedance match network. EM energy at an RF frequency is inductively coupled from inductive coil through a dielectric window (not shown) to plasma 125. A typical frequency for the application of RF power to the inductive coil can range from about 10 MHz to about 100 MHz. In addition, a slotted Faraday shield (not shown) can be employed to reduce capacitive coupling between the inductive coil and plasma 125.

An impedance match network may serve to improve the transfer of RF power to plasma 125 by reducing the reflected power. Match network topologies (e.g. L-type, π-type, T-type, etc.) and automatic control methods are well known to those skilled in the art.

The inductive coil may include a helical coil. Alternatively, the inductive coil can be a “spiral” coil or “pancake” coil in communication with the plasma 125 from above as in a transformer coupled plasma (TCP). The design and implementation of an inductively coupled plasma (ICP) source, or transformer coupled plasma (TCP) source, is well known to those skilled in the art.

In an electropositive discharge, the composition of the plasma includes electrons and positively charged ions. Using a quasi-neutral plasma approximation, the number of free electrons is equivalent to the number of singly charged positive ions. As an example, in an electropositive discharge, the electron density may range from approximately 10¹⁰ cm⁻³ to 10¹³ cm⁻³, and the electron temperature may range from about 1 eV to about 10 eV (depending on the type of plasma source utilized).

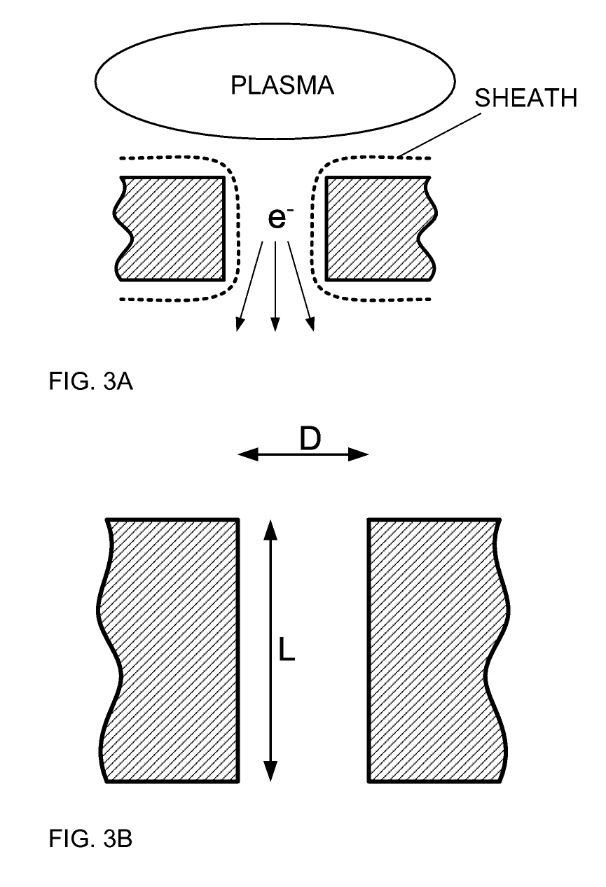

Referring still to FIG. 2, a separation member 150 is disposed between the first chamber region 120 and the second chamber region 130, wherein the separation member 150 comprises one or more openings 152 configured to allow transport of electrons from plasma 125 in the first chamber region 120 to the second chamber region 130 in order to form a quiescent plasma 135 (indicated by dashed line) in the second chamber region 130. The one or more openings 152 in the separation member 150 may comprise super-Debye length apertures, i.e., the transverse dimension or diameter is larger than the Debye length. The one or more openings 152 may be sufficiently large to permit adequate electron transport, and the one or more openings 152 may be sufficiently small to prevent or reduce electron heating across the separation member 150. FIG. 3A provides a schematic cross-section of an opening through the separation member that illustrates the dimension of the plasma sheath relative to the transverse dimension of the opening, wherein electrons (e⁻) emerge from the plasma.

In the second chamber region 130, the process chamber 110 and the separation member 150 may be fabricated from a dielectric material, such as SiO₂ or quartz. A dielectric material may minimize charge-loss and eliminate a current path through the chamber.

Additionally, a pressure control system is coupled to the processing system 100, and configured to control the second pressure. Electrons from the first chamber region 120 may undergo collision-quenching with the second process gas to form less energetic electrons that produce the quiescent plasma 135 with negatively-charged ions in the second chamber region 130. For example, the electrons emerging through the separation member 150 may have an electron temperature of about 1 eV and, when the electron temperature decreases to about 0.05 to about 0.1 eV, efficient negative ion production can occur. As illustrated in FIG. 2, the pressure control system is coupled to the second chamber region 130; however, it may be coupled to the first chamber region 110, or it may be coupled to the first chamber region 110 and the second chamber region 120.

The pressure control system comprises a pumping system 170 coupled to the process chamber 110 via a pumping duct 172, a valve 174 coupled to the pumping duct 172 and located between the pumping system 170 and the process chamber 110, and a pressure measurement device 176 coupled to the process chamber 110 and configured to measure the second pressure. A controller 180 coupled to the pressure measurement device 176, the pumping system 170 and the valve 174 may be configured to perform at least one of monitoring, adjusting or controlling the second pressure.

The pumping system 170 may include a turbo-molecular vacuum pump (TMP) capable of a pumping speed up to 5000 liters per second (and greater). In conventional plasma processing devices utilized for dry plasma etch, a 1000 to 3000 liter per second TMP can be employed. TMPs can be used for low pressure processing, typically less than 50 mTorr. For high pressure processing (i.e., greater than 100 mTorr), a mechanical booster pump and dry roughing pump can be used. Furthermore, the pressure measurement device 176 for monitoring chamber pressure may be coupled to the process chamber 110. The pressure measurement device 176 may be, for example, a relative or absolute capacitance manometer, such as one commercially available from MKS Instruments, Inc. (Andover, Mass.).

The pressure control system may further comprise an exhaust cylinder 178 coupled to process chamber 110, through which process chamber 110 may be evacuated to reduced pressure (e.g., a vacuum pressure less than atmospheric pressure). The exhaust cylinder 178 comprises one or more openings that may comprise a transverse dimension (or diameter) which is smaller than a Debye length (sub-Debye) or is larger than a Debye length (super-Debye). Additionally, the exhaust cylinder 178 may be electrically biased or coupled to ground.

According to one example, the exhaust cylinder 178 comprises one or more sub-Debye openings, and the exhaust cylinder 178 is electrically biased at a negative voltage. Positively charged ions and neutral gases may be pumped through the exhaust cylinder 178. The one or more openings may, for instance, be approximately 1 mm in diameter and 3 mm in length.

According to another example, the exhaust cylinder 178 comprises one or more super-Debye openings, and the exhaust cylinder 178 is coupled to ground. Gases may be pumped through the exhaust cylinder 178 with relatively high flow conductance.

The exhaust cylinder 178 may be fabricated from a conductive material. For example, the exhaust cylinder 178 may be fabricated from RuO₂ (ruthenium oxide) or Hf (hafnium).

Processing system 100 also comprises a neutralizer grid 190 coupled to an outlet of the process chamber 110, and configured to partly or fully neutralize the negatively charged ions. The neutralizer grid 190 comprises one or more apertures 192 for neutralizing ion species as these species pass through. The neutralizer grid 190 may be coupled to ground or it may be electrically biased. The neutralizer grid 190 may be a sub-Debye neutralizer grid. The one or more apertures 192 may, for instance, be approximately 1 mm in diameter and 12 mm in length.

If the diameter (or transverse dimension(s)) of the one or more apertures 172 is on the order of or smaller than the Debye length (i.e., a sub-Debye dimension) and the aspect ratio (i.e., ratio of longitudinal dimension L to transverse dimension d; see FIG. 3B) is maintained at approximately 1:1 or larger, then the geometry of the plasma sheath is substantially unaffected from the geometry which would be caused by an un-apertured neutralizer grid (i.e., a planar wall) and remains substantially planar.

Therefore, a region where ion and electron recombination are favored will exist adjacent to but not necessarily within the aperture and the number of energetic neutral particles will be made to increase relative to the ion population. Furthermore, plasma formed upstream of the neutralizer grid is confined and does not form a charged particle flux through the aperture. The flux of particles through the aperture, however, will also contain some effusive neutral beam component, although the effusive neutral beam component may be reduced by increasing the aspect ratio of the one or more apertures.

The neutralizer grid 190 may be fabricated from a conductive material. For example, the neutralizer grid 190 may be fabricated from RuO₂ or Hf.

Additional details for a hyperthermal neutral beam source having a sub-Debye length neutralizer grid is provided in U.S. Pat. No. 5,468,955, entitled “Neutral beam apparatus for in-situ production of reactants and kinetic energy transfer”.

Referring still to FIG. 2, processing system 100 further comprises a controller 180 that comprises a microprocessor, memory, and a digital I/O port capable of generating control voltages sufficient to communicate and activate inputs to processing system 100 as well as monitor outputs from processing system 100. Moreover, controller 180 can be coupled to and can exchange information with the plasma generation system 160, the pressure control system, the first gas injection system 122, the second gas injection system 132, and any electrical bias system (not shown) coupled to neutralizer grid 190. A program stored in the memory can be utilized to activate the inputs to the aforementioned components of processing system 100 according to a process recipe for forming a negative ion plasma. One example of controller 180 is a DELL PRECISION WORKSTATION 610™, available from Dell Corporation, Austin, Tex.

Controller 180 may be locally located relative to the processing system 100, or it may be remotely located relative to the processing system 100 via an internet or intranet. Thus, controller 180 can exchange data with the processing system 100 using at least one of a direct connection, an intranet, or the internet. Controller 180 may be coupled to an intranet at a customer site (i.e., a device maker, etc.), or coupled to an intranet at a vendor site (i.e., an equipment manufacturer). Furthermore, another computer (i.e., controller, server, etc.) can access controller 180 to exchange data via at least one of a direct connection, an intranet, or the internet.

Furthermore, embodiments of this invention may be used as or to support a software program executed upon some form of processing core (such as a processor of a computer, e.g., controller 180) or otherwise implemented or realized upon or within a machine-readable medium. A machine-readable medium includes any mechanism for storing information in a form readable by a machine (e.g., a computer). For example, a machine-readable medium can include such as a read only memory (ROM); a random access memory (RAM); a magnetic disk storage media; an optical storage media; and a flash memory device, etc.

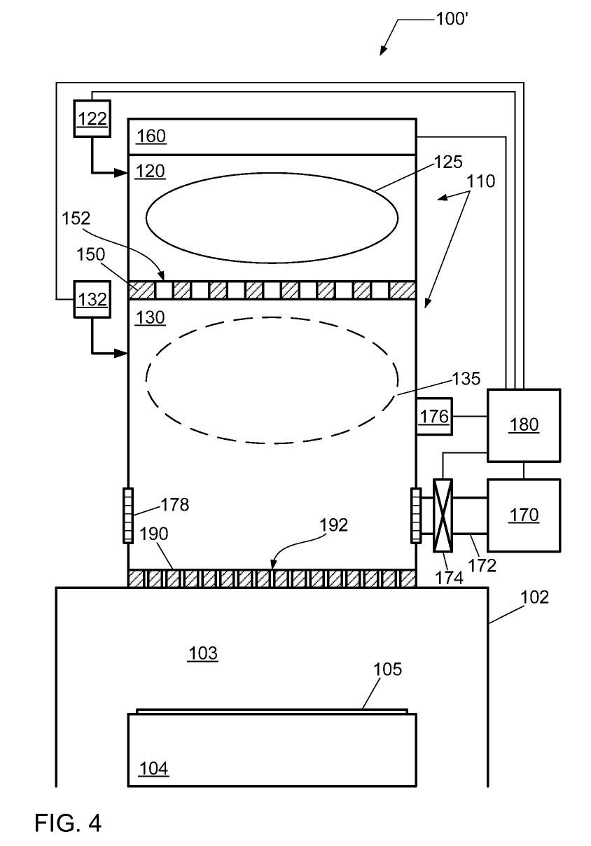

Referring now to FIG. 4, a processing system 100′ is provided for producing a negative ion plasma according to an embodiment. As illustrated in FIG. 4, the processing system 100′ is coupled to a substrate treatment system 102 that provides a substrate treatment region 103 for treating a substrate 105 on a substrate holder 104. The substrate 105 may be treated with a neutral beam, or it may be treated with a negative ion plasma if the neutralizer grid 190 is either omitted or designed with super-Debye apertures.

The substrate holder 104 can comprise a temperature control system having a cooling system or a heating system or both. For instance, the cooling system or heating system can include a re-circulating fluid flow that receives heat from substrate holder 104 and transfers heat to a heat exchanger system (not shown) when cooling, or transfers heat from the heat exchanger system to the fluid flow when heating. Additionally, for instance, the cooling system or heating system may comprise heating/cooling elements, such as resistive heating elements, or thermo-electric heaters/coolers located within the substrate holder 104.

Moreover, the substrate holder 104 can facilitate the delivery of heat transfer gas to the back-side of substrate 105 via a backside gas supply system to improve the gas-gap thermal conductance between substrate 105 and substrate holder 104. Such a system can be utilized when temperature control of the substrate is required at elevated or reduced temperatures. For example, the backside gas system can comprise a two-zone gas distribution system, wherein the backside gas (e.g., helium) pressure can be independently varied between the center and the edge of substrate 105.

In other embodiments, heating/cooling elements, such as resistive heating elements, or thermo-electric heaters/coolers can be included in the chamber wall of the substrate treatment system 102 and any other component within the substrate treatment system 102.

If the substrate treatment system 102 is configured for plasma treatment of substrate 105, then the substrate holder may be electrically biased. For example, the substrate holder 104 may be coupled to a RF generator through an optional impedance match network. A typical frequency for the application of power to the substrate holder 104 (or lower electrode) may range from about 0.1 MHz to about 100 MHz.

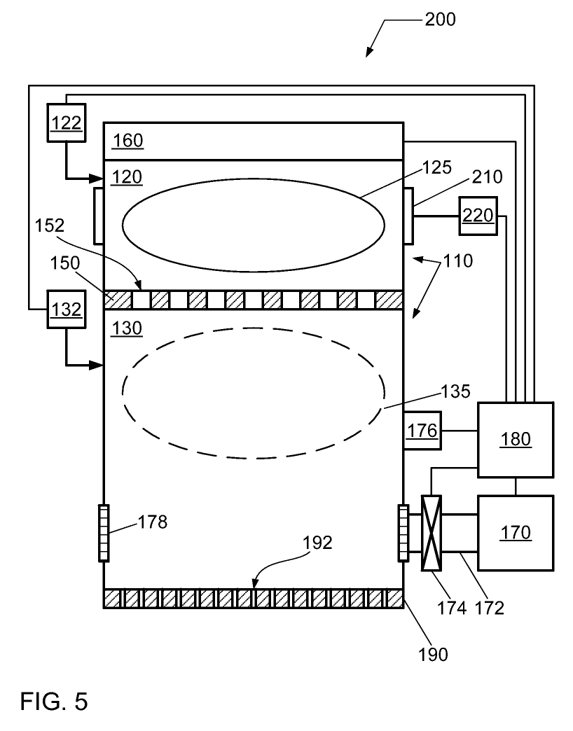

Referring now to FIG. 5, a processing system 200 is provided for producing a negative ion plasma according to an embodiment. The processing system 200 comprises one or more electrodes 210 located about a periphery of the first chamber region 120 and configured to contact plasma 125. A power source 220 is coupled to the one or more electrodes 210 and configured to couple an electrical voltage to the one or more electrodes 210. The one or more electrodes 210 may include a powered cylindrical electrode configured to act as a cylindrical hollow-cathode. For example, the one or more electrodes 210 may be utilized to reduce the plasma potential of plasma 125 formed in the first chamber region 120 or reduce the electron temperature or both.

The power source 220 may comprise a direct current (DC) power supply. The DC power supply can include a variable DC power supply. Additionally, the DC power supply can include a bipolar DC power supply. The DC power supply can further include a system configured to perform monitoring, adjusting, or controlling the polarity, current, voltage, or on/off state of the DC power supply or any combination thereof. An electrical filter may be utilized to de-couple RF power from the DC power supply.

For example, the DC voltage applied to the one or more electrodes 210 by power source 220 may range from approximately −5000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. For example, the DC voltage may range from about −1 V to about −5 kV, and desirably the DC voltage may range from about −1 V to about −2 kV.

Furthermore, it is desirable that the DC voltage is a negative voltage suitable for reducing the plasma potential of plasma 125 or reducing the electron temperature or both. For example, by reducing the plasma potential of plasma 125 relative to the plasma potential of quiescent plasma 135, electric field enhanced diffusion of electrons between the first chamber region 120 and the second chamber region 130 can occur. Furthermore, for example, by reducing the electron temperature of plasma 125, less collisions are required in the second chamber region 130 to produce electron energies for efficient production of negative ions.

The one or more electrodes 210 may be fabricated from a conductive material. For example, the one or more electrode 210 may be fabricated from RuO₂ or Hf.

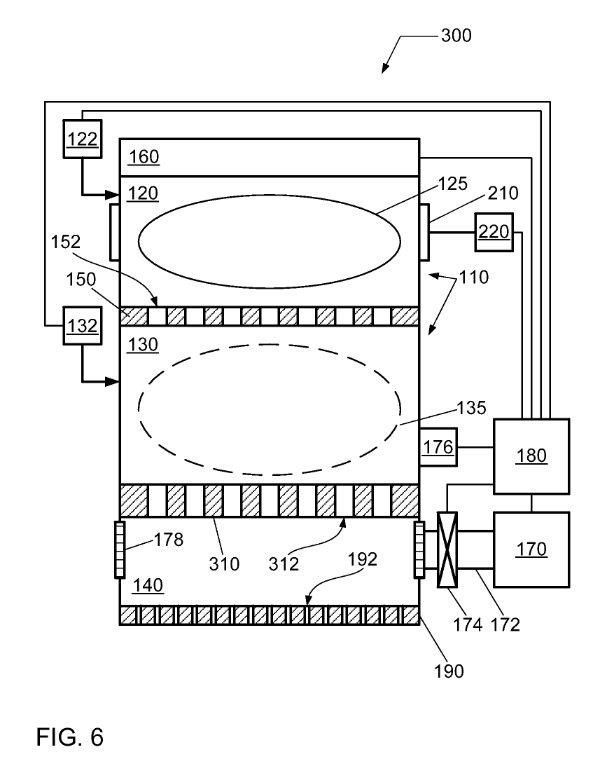

Referring now to FIG. 6, a processing system 300 is provided for producing a negative ion plasma according to an embodiment. The processing system 300 may further comprise a third chamber region 140 disposed downstream of the second chamber region 130, wherein an outlet of the third chamber region 140 is coupled to the neutralizer grid 190. A pressure barrier 310 may be disposed between the second chamber region 130 and the third chamber region 140, and configured to produce a pressure difference between the second pressure in the second chamber region 130 and a third pressure in the third chamber region 140, the third pressure less than the second pressure. The pressure barrier 310 comprises one or more openings 312 that may comprise super-Debye length apertures. The one or more openings 312 may be sufficiently small to allow a pressure difference between the second chamber region 130 and the third chamber region 140. By introducing pressure barrier 310, the second pressure may be increased, which may be beneficial for efficient collision-quenching in the second chamber region 130.

The pressure barrier 310 may be fabricated from a dielectric material, such as SiO₂ or quartz.

According to an example, when producing a neutral beam for treating a substrate in a substrate treatment region (e.g., substrate treatment region 103 in FIG. 4), the first pressure may range from about 10 mTorr to about 100 mTorr (e.g., about 50-70 mTorr); the second pressure may range from about 10 mTorr to about 100 mTorr (e.g., about 50-70 mTorr); the third pressure may range from about 1 mTorr to about 10 mTorr (e.g., about 3-5 mTorr); and the pressure in the substrate treatment region may less than about 1 mTorr (e.g., about 0.1-0.3 mTorr). A vacuum pumping system coupled to the third chamber region may provide a pumping speed of about 1000 liters per second (l/sec), and a vacuum pumping system coupled to the substrate treatment region may provide a pumping speed of about 3000 l/sec. The flow conductance through the pressure barrier may be about 10 l/sec to about 500 l/sec (e.g., about 50 l/sec), and the flow conductance through the neutralizer grid may be about 100 l/sec to about 1000 l/sec (e.g., about 300 l/sec).

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A processing system for producing plasma containing negatively-charged ions, comprising:
a first chamber configured to receive a first process gas and operate at a first pressure;
a first gas injection system coupled to said first chamber and configured to introduce said first process gas;
a second chamber coupled to said first chamber, and configured to receive a second process gas and operate at a second pressure, wherein said second chamber comprises an outlet configured to be coupled to a substrate treatment system for processing a substrate;
a second gas injection system coupled to said second chamber and configured to introduce said second process gas;
a plasma generation system coupled to system first chamber and configured to form plasma from said first process gas;
a separation member disposed between said first chamber and said second chamber, wherein said separation member comprises one or more openings configured to supply electrons from said plasma in said first chamber to said second chamber in order to form a quiescent plasma in said second chamber; and
a pressure control system coupled to said first chamber or said second chamber or both, and configured to control said second pressure such that said electrons from said first chamber undergo collision-quenching with said second process gas to form less energetic electrons that produce said quiescent plasma with negatively-charged ions in said second chamber,
wherein said second process gas comprises at least one electronegative gaseous specie.

2. The processing system of claim 1, wherein said plasma generation system comprises at least one of a capacitively coupled plasma source, an inductively coupled plasma source, a transformer coupled plasma source, a microwave plasma source, a surface wave plasma source, or a helicon wave plasma source.

3. The processing system of claim 1, wherein said plasma generation system comprises a transformer coupled plasma source having an inductive coil positioned above said first chamber and configured to couple electromagnetic (EM) energy through a dielectric window to the interior of said first chamber.

4. The processing system of claim 1, further comprising:
one or more electrodes located about a periphery of said first chamber and configured to contact said plasma; and
a power source coupled to said one or more electrodes and configured to couple an electrical voltage to said one or more electrodes.

5. The processing system of claim 1, further comprising:
a cylindrical electrode surrounding a periphery of said first chamber and configured to contact said plasma; and
a power source coupled to said cylindrical electrode and configured to couple an electrical voltage to said cylindrical electrode.

6. The processing system of claim 5, wherein said powered cylindrical electrode is configured to act as a cylindrical hollow-cathode, and wherein said electrical voltage comprises a direct current (dc) voltage ranging from about −1 V (volt) to about −5 kV.

7. The processing system of claim 6, wherein said electrical voltage comprises a direct current (dc) voltage ranging from about −1 V (volt) to about −2 kV.

8. The processing system of claim 1, wherein said pressure control system comprises a pumping system coupled to said second chamber via a pumping duct, a valve coupled to said pumping duct and located between said pumping system and said second chamber, a pressure measurement device coupled to said second chamber and configured to measure said second pressure, and a controller coupled to said pressure measurement device and said valve and configured to perform at least one of monitoring, adjusting or controlling said second pressure.

9. The processing system of claim 1, further comprising:
a neutralizer grid coupled to said outlet of said second chamber, and configured to partly or fully neutralize said negatively charged ions.

10. The processing system of claim 9, wherein said neutralizer grid comprises a sub-Debye neutralizer grid.

11. The processing system of claim 1, further comprising:
a third chamber coupled to said second chamber and proximate said outlet of said second chamber, wherein a pressure barrier is disposed between said second chamber and said third chamber and configured to produce a pressure difference between said second pressure in said second chamber and a third pressure in said third chamber, said third pressure less than said second pressure.

12. The processing system of claim 11, wherein said pressure control system is coupled to said third chamber.

13. The processing system of claim 11, further comprising:
a neutralizer grid coupled to said outlet of said third chamber, and configured to partly or fully neutralize said negatively charged ions.

14. The processing system of claim 13, wherein said neutralizer grid comprises a sub-Debye neutralizer grid.

15. A negatively-charged-ion-generated neutral beam source, comprising:
a neutral beam generation chamber comprising a first chamber region configured to receive a first process gas and operate at a first pressure, and a second chamber region disposed downstream of said first chamber region and configured to receive a second process gas and operate at a second pressure;
a first gas injection system coupled to said first chamber region and configured to introduce said first process gas;
a second gas injection system coupled to said second chamber region and configured to introduce said second process gas;
a plasma generation system coupled to said first chamber region and configured to form plasma from said first process gas;
a separation member disposed between said first chamber region and said second chamber region, wherein said separation member comprises one or more openings configured to allow the transport of electrons from said plasma in said first chamber region to said second chamber region in order to form a quiescent plasma in said second chamber region;
a pressure control system coupled to said neutral beam generation chamber, and configured to control said second pressure such that said electrons from said first chamber region undergo collision-quenching with said second process gas to form less energetic electrons that produce said quiescent plasma with negatively-charged ions; and
a sub-Debye neutralizer grid coupled to said outlet of said second chamber region, and configured to partly or fully neutralize said negatively charged ions.

16. The neutral beam source of claim 15, further comprising:
a third chamber region disposed downstream of said second chamber region, wherein an outlet of said third chamber region is coupled to said sub-Debye neutralizer grid.

17. The neutral beam source of claim 16, further comprising:
a pressure barrier disposed between said second chamber region and said third chamber region and configured to produce a pressure difference between said second pressure in said second chamber region and a third pressure in said third chamber region, said third pressure less than said second pressure.

18. The neutral beam source of claim 17, further comprising:
a cylindrical electrode surrounding a periphery of said first chamber region and configured to contact said plasma; and
a power source coupled to said cylindrical electrode and configured to couple an electrical voltage to said cylindrical electrode,
wherein said powered cylindrical electrode is configured to act as a cylindrical hollow-cathode, and wherein said electrical voltage comprises a direct current (dc) voltage ranging from about −1 V (volt) to about −5 kV.

19. The neutral beam source of claim 18, wherein said pressure control system is coupled to said third chamber region through an exhaust cylinder that is grounded or is electrically biased, and wherein said exhaust cylinder comprises one or more sub-Debye openings formed there through, or one or more super-Debye openings formed there through, or a combination thereof.

20. A processing system for producing plasma containing negatively-charged ions, comprising:
a process chamber comprising a first chamber region and a second chamber region;
means for forming plasma from a first process gas in said first chamber region;
means for separating said first chamber region from said second chamber region;
means for transporting electrons from said plasma in said first chamber region to said second chamber region; and
means for forming negatively-charged ions from a second process gas in said second chamber region using said transported electrons.
